(19) United States
(12) Patent Application Publication
(10) Pub. No.: US 2016/0149119 A1
(43) Pub. Date: May 26, 2016

(54) PIEZOELECTRIC CERAMIC COMPOSITION, PIEZOELECTRIC ELEMENT, AND METHOD FOR THE SAME

(71) Applicant: SAMSUNG ELECTRO-MECHANICS CO., LTD., Suwon-Si (KR)

(72) Inventors: Hong-Yeon CHO, Suwon (KR); Yong-Koo KIM, Pocheon (KR); Woo-Sup KIM, Seoul (KR); Boum-Seock KIM, Suwon (KR)

(21) Appl. No.: 14/945,340

(22) Filed: Nov. 18, 2015

(30) Foreign Application Priority Data
Nov. 21, 2014 (KR) 10-2014-0163748

(51) Int. Cl. H01L 41/187; H01L 41/09; H01L 41/047; C04B 35/495; C04B 35/64

(52) U.S. Cl. CPC H01L 41/187; C04B 35/495; C04B 35/64; H01L 41/0471; H01L 41/09

(57) ABSTRACT

A piezoelectric ceramic composition comprises a basic composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃, wherein x=0 or 0.015 y=0.47-0.53, and at least one sintering aid of LiCO₃, CaCO₃, PbO, CuO and Fe₂O₃, a piezoelectric element comprising the composition, and a method for preparing the same. The piezoelectric ceramic composition allows low temperature sintering and the piezoelectric ceramics prepared therefrom improves structural property, piezoelectric property and dielectric property.

### CROSS REFERENCE TO RELATED APPLICATION

This application claims the benefit of Korean Patent Application No. 10-2014-0163748, filed on Nov. 21, 2014, entitled “Piezoelectric ceramic composition, piezoelectric element and method for the same”, which is hereby incorporated by reference in its entirety into this application.

### TECHNICAL FIELD

The present disclosure relates to a piezoelectric ceramic composition and a piezoelectric element.

### BACKGROUND

Piezoelectric ceramics, in which an internal electrode layer composed of an Ag—Pd alloy and a ceramic layer composed of PZT-based piezoelectric ceramics are alternatively laminated and calcinated at the same time, are mainly used for multilayer piezoelectric elements such as piezoelectric actuators, piezoelectric resonators, piezoelectric filters and the like. Due to wide applications and increasing demand for environmentally-friendly processes, studies of adding new components to the conventional piezoelectric ceramics have been actively made. For example, KR Patent Publication No. 1994-0022936 discloses a piezoelectric ceramic composition having high mechanical coupling coefficient.

### SUMMARY

An object of the present disclosure is to provide a piezoelectric ceramic composition for which properties are not deteriorated during operation in a high electric field, a piezoelectric element, and a method for preparing piezoelectric ceramics using the same.

According to the present disclosure, there are provided a piezoelectric ceramic composition comprising a basic composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃ (x=0 or 0.015, y=0.47-0.53) (Composition 1) and at least one sintering aid selected from the group consisting of LiCO₃, CaCO₃, PbO, CuO and Fe₂O₃, a piezoelectric element comprising the composition and a method for preparing piezoelectric ceramics.

The piezoelectric ceramic composition according to the present disclosure allows low temperature sintering and the piezoelectric ceramics prepared by using the composition improve structural property, piezoelectric property and dielectric property.

### BRIEF DESCRIPTION OF THE DRAWINGS

FIG. 1 illustrates X-ray diffraction patterns depending on the amount of Fe₂O₃ to a PMW-PNN-PZT ceramic composition.

FIG. 2 illustrates densities of sample depending on the sintering temperature and the amount of Fe₂O₃.

FIG. 3 illustrates SEM images of sample surfaces to observe microstructure of samples prepared by adding Fe₂O₃ to a PMW-PNN-PZT ceramic composition and calcinating the mixture at 920° C.

FIG. 4 and FIG. 5 illustrate changes in electromechanical coupling coefficients k₃₁ (FIG. 4) and kₚ (FIG. 5) depending on the sintering temperature and the amount of Fe₂O₃.

FIG. 6 and FIG. 7 illustrate changes in piezoelectric constants d₃₃ (FIG. 6) and d₃₁ (FIG. 7) of sample depending on the sintering temperature and the amount of Fe₂O₃.

FIG. 8 illustrates changes in dielectric constant (∈ᵣ) depending on the sintering temperature and the amount of Fe₂O₃.

FIG. 9 illustrates X-ray diffraction patterns of final powders of a PMW-PNN-PZT+BiFeO₃ composition and the sintered pellet thereof.

FIG. 10 illustrates an SEM image of PMW-PNN-PZT+BiFeO₃ ceramics.

FIG. 11 illustrates temperature dependence of dielectric constant of PMW-PNN-PZT+BiFeO₃ ceramics which are sintered at 920° C. by using a conventional mixed-oxide method.

FIG. 12 illustrates X-ray diffraction patterns depending on various sintering aid types added to a PMW-PNN-PZT ceramic composition.

FIG. 13 illustrates X-ray diffraction patterns depending on various types of sintering aids added to a PMW-PNN-PZT ceramic composition.

FIG. 14 is a graph illustrating dielectric constants depending on Zr/Ti ratios.

FIG. 15 is a graph illustrating electromechanical coupling coefficients depending on Zr/Ti ratios.

FIG. 16 is a graph illustrating piezoelectric constants depending on Zr/Ti ratios.

FIG. 17 is a graph illustrating coercive fields depending on Zr/Ti ratios.

### DETAILED DESCRIPTION

While the present disclosure has been described with reference to particular embodiments, it is to be appreciated that various changes and modifications may be made by those skilled in the art without departing from the spirit and scope of the present disclosure, as defined by the appended claims and their equivalents. Throughout the description of the present disclosure, when describing a certain technology is determined to evade the point of the present disclosure, the pertinent detailed description will be omitted.

While such terms as “first” and “second,” etc., may be used to describe various components, such components must not be limited to the above terms. The above terms are used only to distinguish one component from another.

The terms used in the description are intended to describe certain embodiments only, and shall by no means restrict the present disclosure. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, the present disclosure will be explained in detail.

The inventors of the present disclosure have selected PMW-PNN-PZT composition ceramics to develop low temperature sintering piezoelectric ceramics and additionally used at least one chosen from LiCO₃, CaCO₃, PbO, CuO and Fe₂O₃ as a sintering aid. Dielectric and piezoelectric properties at up to 900° C.-940° C. of a sintering temperature are determined by adding LiCO₃ and CaCO₃ as the sintering aid or changing the content of Fe₂O₃ while maintaining the content of PbO and CuO.

According to an aspect of the present disclosure, there is provided a piezoelectric ceramic composition including a basic composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃, where x=0 or 0.015, and y=0.47-0.53 and at least one sintering aid chosen from LiCO₃, CaCO₃, PbO, CuO and Fe₂O₃.

In an embodiment of the present disclosure, the sintering aid may be 0.2 wt % LiCO₃ and 0.25 wt % CaCO₃ based on a total weight of the piezoelectric ceramic composition.

In an embodiment of the present disclosure, the sintering aid may be 0.3 wt % PbO, 0.3 wt % CuO, and 0.1-0.4 wt % Fe₂O₃ based on a total weight of the piezoelectric ceramic composition.

According to another aspect of the present disclosure, a method is provided for preparing a piezoelectric ceramic composition including mixing PbO, MgO, WO, NiO, Nb₂O₅, ZrO₂, and TiO₂ to prepare a basic composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃, wherein x=0 or 0.015 and y=0.47-0.53. A first calcination of the mixture of the MgO, WO, NiO, Nb₂O₅, ZrO₂, and TiO₂ is performed. The first calcinated sample and PbO are mixed and then pulverized, and a second calcination is performed. 0.3 wt % PbO, 0.3 wt % CuO, 0.1-0.4 wt % Fe₂O₃ based on a total weight of the piezoelectric ceramic composition, or 0.2 wt % LiCO₃ and 0.25 wt % CaCO₃ based on a total weight of the piezoelectric ceramic composition are added to the second calcinated sample and the mixture is pulverized and then sintered.

In an embodiment of the present disclosure, the sintering may be performed at a temperature of 900° C.-940° C. for 2 hours with a rising dropping temperature gradient of 3° C./min.

According to another aspect of the present disclosure, there is provided a piezoelectric element including a piezoelectric ceramic composition according to an embodiment of the present disclosure. The piezoelectric element may include a piezoelectric actuator, a piezoelectric resonator, a piezoelectric filter, a piezoelectric sensor, an ultrasonic transducer, and an efficient capacitor, etc. but it is not limited thereto.

The piezoelectric element according to an embodiment of the present disclosure includes a piezoelectric layer and internal an electrode layer. The piezoelectric layer includes a piezoelectric ceramic composition according to an embodiment of the present disclosure. When charge is applied to at least one of the top and the bottom of the piezoelectric layer by the internal electrode layer, it causes mechanical displacement of the piezoelectric layer. The internal electrode layer applies charge to the piezoelectric layer by being formed on at least one of the top and the bottom of the piezoelectric layer. The Internal electrode layer applies charge to the piezoelectric layer by being connected with an external electrode layer. The internal electrode layer may include an Ag—Pd alloy. The internal electrode layer includes high amount of palladium having a melting temperature of 1500° C. or higher since when the piezoelectric layer and the internal electrode layer of the multilayer piezoelectric element are sintered at the same time, the internal electrode layer should not be oxidized at a temperature of 1100° C., which is a general sintering temperature of the piezoelectric layer.

According to an embodiment of the present disclosure, a palladium content in the Ag—Pd alloy which is included in the internal electrode layer may be between more than 0 wt % and 10 wt %. Since the piezoelectric ceramic composition, according to an embodiment of the present disclosure, can be sintered at a low temperature sintering (a low temperature in the entire disclosure refers to a temperature equal to or less than 950° C.), even though the content of expensive palladium is limited to the above-mentioned range, it provides an internal electrode layer without any deformation or crack when it is sintered at the same time.

Such a piezoelectric element according to an embodiment of the present disclosure, which can be sintered at a low temperature, reduces the palladium content, which is composed in the internal electrode layer, and further significantly reduces manufacturing cost.

According to an embodiment of the present disclosure, the piezoelectric element may be a piezoelectric actuator. The actuator may be formed in multilayers having a piezoelectric layer including a piezoelectric ceramic composition according to an embodiment of the present disclosure, which can be sintered at a low temperature, and an internal electrode layer which applies charge to the piezoelectric layer by being formed on at least one of the top and the bottom of the piezoelectric layer. Piezoelectric deformation may be caused to the actuator due to the piezoelectric ceramic composition when voltage is applied to the piezoelectric layer through the internal electrode layer. Since the piezoelectric layer and the internal electrode layer have been described when the piezoelectric element is described, detailed description thereabout will be omitted.

Exemplary embodiments of the present disclosure will be described in more detail with reference to accompanying drawings.

Preparation of Sample I

PMW-PNN-PZT composition ceramics were selected to develop low temperature sintering piezoelectric ceramics, and PbO, CuO, and Fe₂O₃ as sintering aids were mixed to minimize non-homogeneities caused by low temperature sintering and difference in reactivity of each component of a B site using a columbite precursor method. Here, dielectric and piezoelectric properties were determined depending on a sintering temperature of 900° C.-940° C. while changing the Fe₂O₃ content and maintaining the contents of PbO and CuO.

The composition which was used for experiments is as the following composition 2.

(1-x)Pb(Mg_{1/2}W_{1/2})_{0.33}(Ni_{1/3}Nb_{2/3})_{0.09}(Zr_{y}Ti_{1-y})_{0.88}O₃+xBiFeO₃, wherein x=0 or 0.015 and y=0.47-0.53, +0.3 wt % PbO+0.3 wt % CuO+z wt % Fe₂O₃ wherein z=0-0.4 (Composition 2)

B-site components of MgO, WO, NiO, Nb₂O₅, ZrO₂, and TiO₂ having a purity of 99% or higher were weighed out, mixed, and pulverized in acetone as a dispersion medium using 3φ zirconia ball for 24 hours. The ball-milled mixture was fully dried in a constant temperature-drying oven for more than 12 hours and then calcinated in an alumina crucible at 1100° C. for 4 hours. The calcinated sample and PbO were mixed and pulverized for 24 hours to provide a perovskite PMW-PNN-PZT sample. The mixed and pulverized sample was dried and then calcinated at 750° C. for 2 hours. PbO, CuO and Fe₂O₃ as sintering aids were added to the second calcinated sample and the mixture was mixed and pulverized for 24 hours. PVA (5 wt % aqueous solution) was added to the dried sample and the mixture was molded using a 17φ molder under a molding pressure of 15 MPa. Burn out was then performed at 600° C. for 3 hours. The prepared sample was sintered with rising dropping temperature gradient of 3° C./min at a sintering temperature of 900° C.-940° C. for 2 hours.

1) Determination of Piezoelectric and Dielectric Properties of Samples

The sintered sample was polished with 1 mm and both sides thereof were coated with an Ag electrode by using a screen printing method and then heat-treated at 600° C. to determine properties. The sample was polarized by applying 3 kV/mm of DC electric field in silicon oil of 120° C. for 30 minutes.

Electrostatic capacity was determined at 1 kHz using an LCR meter (ANDO AG-4304) to obtain a dielectric constant which determined the dielectric property of the sample. Microstructure and crystal structure of the sample were determined by using SEM (Scanning Electron Microscope) and XRD (X-ray Diffraction), respectively. Particle size was determined by using a linear intercept technical method and piezoelectric constant (d₃₃) was determined by using a charge detector (8000 piezo d₃₃ tester). Resonance and antiresonance frequency and resonant resistance were determined by using an impedance analyzer (Agilent 4294A) according to the IEEE standard to obtain electromechanical coupling coefficient (k_{P}) and mechanical quality coefficient (Qₘ).

2) Sintering and Structural Properties of Samples

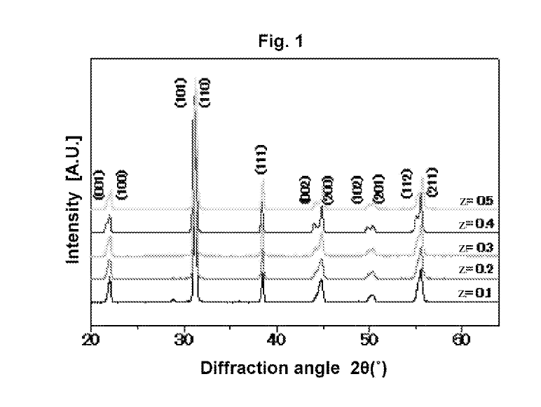

FIG. 1 illustrates X-ray diffraction patterns depending on the amount of Fe₂O₃ added to a PMW-PNN-PZT ceramic composition. All samples have a general perovskite structure in X-ray diffraction patterns in FIG. 1. The sample to which Fe₂O₃ was not added shows secondary phase, while the other samples show no secondary phase as the amount of Fe₂O₃ added increases. This result indicates complete solid state reaction.

As shown in FIG. 1, it is noted that a (002) peak increases as the amount of Fe₂O₃ added increases, which further identifies an increase in tetragonality.

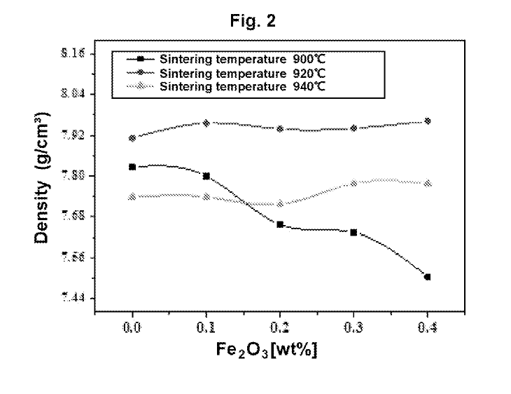

FIG. 2 illustrates densities of samples depending on the sintering temperature and the amount of Fe₂O₃. It is noted that when the sintering temperature is 900° C., the density slowly decreases as the amount of Fe₂O₃ added increases since the sintering temperature of 900° C. is low for complete liquid phase sintering. When the sintering temperature is 920° C., the sample to which 0.3 wt % of Fe₂O₃ is added shows a maximum density of 7.94 g/cm³. When the sintering temperature is 940° C., the density slowly increases as the amount of Fe₂O₃ added increases as shown in the sintering temperature of 920° C. However, when the density is compared at the sintering temperature of 940° C. with that at a sintering temperature of 920° C., it is noted that the density decreases overall. Therefore, the optimal sintering temperature is 920° C. and such deterioration at 940° C. compared to 920° C. in density is due to an over firing effect.

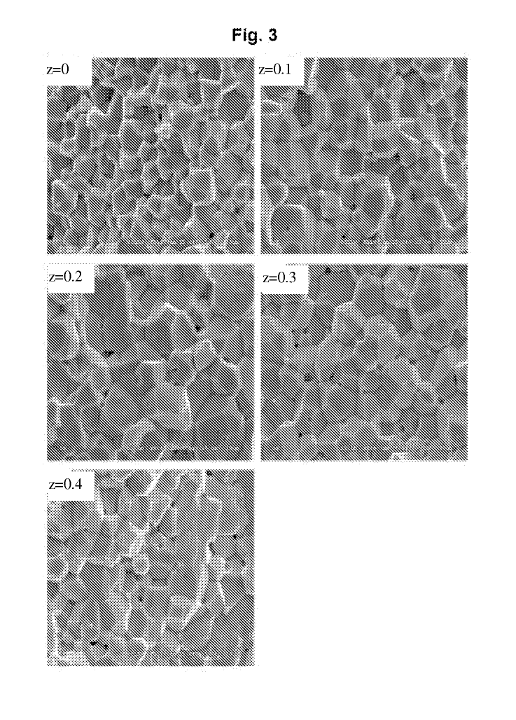

FIG. 3s illustrates SEM images of the surfaces to observe the microstructure of samples prepared by adding Fe₂O₃ to a PMW-PNN-PZT ceramic composition and calcinating the mixture at 920° C. When Fe₂O₃ was added in an amount of z wt % based on the total weight of the composition, where z=0, z=0.1, z=0.2, z=0.3, z=0.4, the average particle size of the samples was 3.21 μm, 3.76 μm, 5.34 μm, 5.49 μm, 4.55 μm, respectively. When the addition amount of Fe₂O₃ was 0.3 wt %, it showed the maximum value of 5.49 μm. The result was associated with an easy formation of the liquid phase of PbO—Fe₂O₃ and PbO—CuO having eutectic points of 730° C. and 680° C., respectively, to allow liquid phase sintering due to a reaction of Fe₂O₃ and CuO with PbO, which were added as sintering aids. This further allows improvement of sinterability and grain growth. On the other hand, when the amount of Fe₂O₃ added was more than 0.3 wt %, the average particle size was reduced due to segregation of Fe₂O₃ around grain boundaries which prevented grain growth.

3) Piezoelectric and Dielectric Properties of Samples

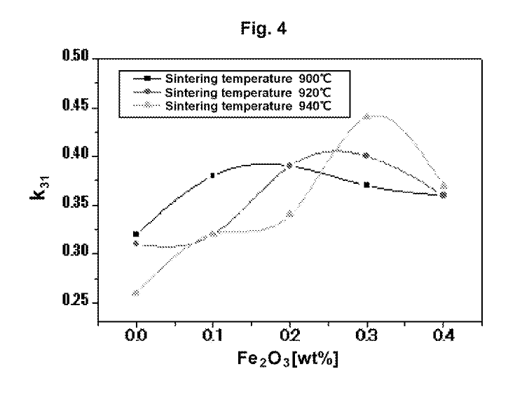

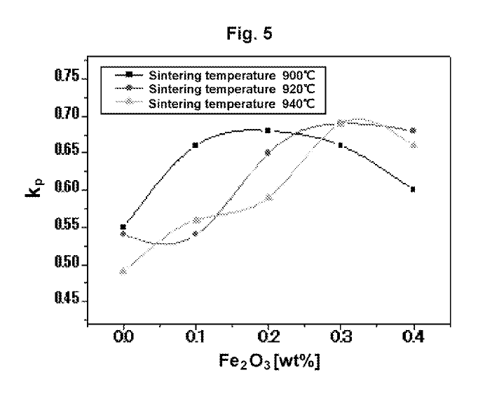

FIG. 4 and FIG. 5 illustrate changes in electromechanical coupling coefficients k₃₁ (FIG. 4) and kₚ (FIG. 5) depending on the sintering temperature and the amount of Fe₂O₃ added.

It is noted that changing tendencies for k₃₁ and k_{P} depending on an increase of the amount of Fe₂O₃ added are similar. When 0.2 wt % of Fe₂O₃ was added at a sintering temperature of 900° C., electromechanical coupling coefficients k₃₁ and k_{P} showed maximum values of 0.39 and 0.68, respectively. k₃₁ and k_{P} slowly increase with the addition of Fe₂O₃, showing the maximum values of 0.4 and 0.69, and 0.44 and 0.69 with the addition of 0.3 wt % Fe₂O₃ at a sintering temperature of 920° C. and 940° C., respectively. When Fe₂O₃ was further added, k₃₁ and k_{P} were decreased. Such a result was associated with the easy formation of the liquid phase of the sintering aids having a low melting point during sintering. This further allows improvement of sinterability, density increase, and grain growth. As shown in SEM images of FIG. 3, it is noted that grains grow with the addition of Fe₂O₃ to facilitate domain switching and polarization which improves electromechanical coupling coefficient. Then grain growth decreases due to decrease in density which deteriorates properties.

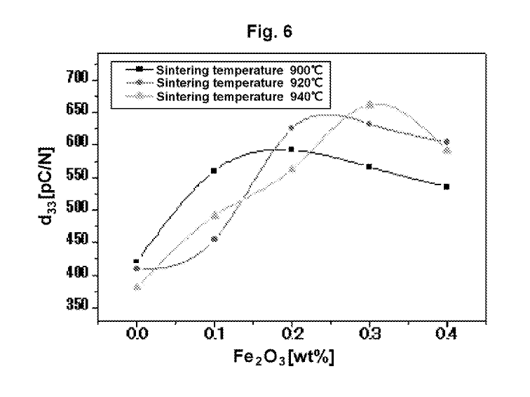

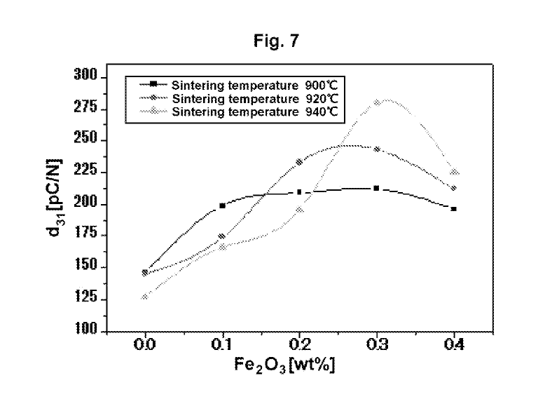

FIG. 6 and FIG. 7 illustrate changes in piezoelectric constant d₃₃ (FIG. 6) and d₃₁ (FIG. 7) depending on the sintering temperature and the amount of Fe₂O₃ added. Piezoelectric constant is a displacement value when the electric field is applied and piezoelectric constants d₃₃ and d₃₁ have similar characteristics to the electromechanical coupling coefficient (k_{P}). It is noted that the piezoelectric constant increases with addition of Fe₂O₃ at a sintering temperature of 900° C. Piezoelectric constants d₃₃ and d₃₁ show the maximum values of 592pC/N and 212pC/N, respectively when 0.2 wt % of Fe₂O₃ is added, while when Fe₂O₃ is added more than 0.2 wt %, piezoelectric constants are decreased. Piezoelectric constants d₃₃ and d₃₁ increase with addition of Fe₂O₃ at a sintering temperature of 920° C. and 940° C. Piezoelectric constants d₃₃ and d₃₁ show the maximum values of 632pC/N and 243pC/N at a sintering temperature of 920° C. and 662pC/N and 280pC/N at a sintering temperature of 940° C. when 0.3 wt % of Fe₂O₃ is added. Such low piezoelectric constants are associated with the low sintering temperature of 900° C. at the composition is not sintered enough. On the other hand, the high piezoelectric constants at a sintering temperature of 920° C. and 940° C. provide an improvement of sinterability and grain growth due to liquid phase sintering as shown in FIG. 3. This further allows improvement of properties due to increase in polarization. As the piezoelectric constant and the electromechanical coupling coefficient are proportional to a dielectric constant and a remanent polarization value, improvement of the piezoelectric constant is associated with increases in the remanent polarization value and the dielectric constant.

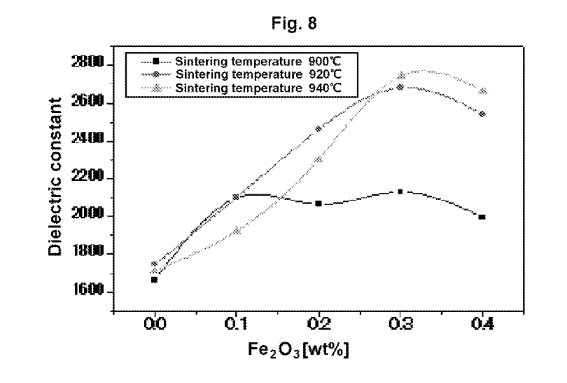

FIG. 8 illustrates changes in the dielectric constant (∈ᵣ) depending on the sintering temperature and the amount of Fe₂O₃ added. The dielectric constant, electromechanical coupling coefficient (kᵣ) and the piezoelectric constant (d₃₃) show an identical trend with each other. The dielectric constant increases with addition of Fe₂O₃ and show a maximum value of 2130, 2682, and 2774 at the sintering temperatures of 900° C., 920° C., and 940° C., respectively, when 0.3 wt % of Fe₂O₃ is added. However, when Fe₂O₃ is added further, the dielectric constant decreases. This result is due to an increase of the density with the addition of Fe₂O₃, a decrease of grain boundary which is a low dielectric layer, and a decrease of porosity resulting from an increase of sintered density as shown the result in FIGS. 2 and 3. A decrease of the dielectric constant is associated with the liquid phase sintering aids, which are not solid solubilized at the grain boundary which is a low dielectric layer.

TABLE 1

| | Sintering | | Electromechanical | Piezoelectric | Coercive |
|---|---|---|---|---|---|
| Fe₂O₃ | temperature | Dielectric | coupling | constant (d₃₁) | field (Ec) |
| (wt %) | [° C.] | constant (εᵣ) | coefficient (K₃₁) | [pC/N] | [kV/cm] |
| 0 | 900 | 1663 | 0.32 | 146 | 9.23 |
| | 920 | 1745 | 0.31 | 145 | 9.52 |
| | 940 | 1714 | 0.26 | 127 | 8.40 |
| 0.1 | 900 | 2099 | 0.38 | 199 | 9.90 |
| | 920 | 2102 | 0.32 | 174 | 10.35 |
| | 940 | 1922 | 0.32 | 166 | 10.05 |
| 0.2 | 900 | 2065 | 0.39 | 209 | 9.67 |
| | 920 | 2460 | 0.39 | 233 | 10.50 |
| | 940 | 2301 | 0.34 | 196 | 9.82 |
| 0.3 | 900 | 2130 | 0.37 | 212 | 10.35 |
| | 920 | 2682 | 0.40 | 246 | 10.80 |
| | 940 | 2744 | 0.44 | 280 | 10.42 |
| 0.4 | 900 | 1997 | 0.36 | 196 | 9.98 |
| | 920 | 2540 | 0.36 | 212 | 10.35 |
| | 940 | 2664 | 0.37 | 225 | 10.13 |

* Values without measurement units represent ratios.

4) Properties (Sintering) of Low Temperature Sintering PMW-PNN-PZT Ceramics with Addition of Fe₂O₃

According to XRD patterns, it is noted that all samples have a pure perovskite structure and an average particle size of the sample is the maximum value of 5.49 μm when 0.3 wt % of Fe₂O₃ is added in the microstructure of the sample sintered at 920° C. However, when Fe₂O₃ is added more than 0.3 wt %, the average particle size decreases.

The density decreases with the addition of Fe₂O₃ at a sintering temperature of 900° C. On the other hand, the density increases at a sintering temperature of 920° C. and 940° C. Particularly, the density shows a maximum value of 7.94 g/cm³ at a sintering temperature of 920° C. when 0.3 wt % of Fe₂O₃ is added.

It is noted that electromechanical coupling coefficient (k_{P}, k₃₁), mechanical quality coefficient Qₘ, piezoelectric constant (d₃₃, d₃₁), dielectric constant (∈ᵣ), coercive field (E_{C}) are 0.69, 0.44, 104.06, 662 pC/N, 280 pC/N, 2744, 10.42 kV/cm, respectively, at a sintering temperature of 940° C. when 0.3 wt % of Fe₂O₃ is added. It is noted that the electromechanical coupling coefficient (k_{P}, k₃₁), mechanical quality coefficient Qₘ, piezoelectric constant (d₃₃, d₃₁), dielectric constant (∈ᵣ), coercive field (E_{C}) are 0.69, 0.40, 213.63, 632 pC/N, 246 pC/N, 2682, 10.80 kV/cm, respectively, at a sintering temperature of 920° C. when 0.3 wt % of Fe₂O₃ is added.

5) Changes in PMW-PNN-PZT Ceramic Properties with Changes in Sintering Temperature

Dielectric and piezoelectric properties of PMW-PNN-PZT ceramics were determined by changing the B-site calcination temperature and the second calcination temperature from 1070° C. to 1100° C. and from 720° C. to 780° C., respectively, using a columbite precursor method. It is noted from the observed XRD patterns that all samples have a pure perovskite structure without the secondary phase (pyrochlore). The average particle size of the samples increases with increasing second calcination temperature at 780° C. after the B-site calcination at 1130° C., and the average particle size of the sample calcinated at 780° C. shows a maximum value of 6.28 μm which is significantly increased, compared to the average particle size of 4.88 μm of the sample calcinated at the B-site calcination temperature of 1100° C. and the second calcination temperature of 750° C.

Density ρ, electromechanical coupling coefficient kₚ, piezoelectric constant d₃₃, dielectric constant ∈ᵣ of the sample show a similar trend with the change in the calcination temperature. k₃₁, d₃₁, S₁₁^{E} increase with an increase in the B-site calcination temperature at 780° C. of the second calcination temperature. Properties show ρ=7.78 g/cm³, kₚ=0.685, k₃₁=0.41, d₃₃=599 pC/N, d₃₁=248 pC/N, 91.57, E_{C}=11.025 kV/cm at the optimal B-site calcination temperature of 1130° C., the second calcination temperature of 750° C., and sintering temperature of 720° C.

Overall piezoelectric and dielectric properties of the samples sintered at 900° C. and 920° C. decrease with an increase in the calcination temperature.

Preparation of Samples II

Basic composition of the present Examples is as follows and samples are prepared by employing a mixed-oxide method.

0.985[Pb(Mg_{1/2}W_{1/2})_{0.03}(Ni_{1/3}Nb_{2/3})_{0.09}(Zr_{0.5}Ti_{0.5})O₃+0.015BiFeO₃+0.2 wt % Li₂CO₃+0.25 wt % CaCO₃ (Composition 3)

PbO (99%), MgO (99%), WO₃ (99%) and the like having a purity of 99% or higher were weighed out, mixed, and pulverized in acetone as a dispersion medium using 3φ zirconia ball for 24 hours. The mixture was dried in a constant temperature-drying oven of 80° C. and then calcinated at 850° C. for 2 hours. The calcinated mixture, BiFeO₃ prepared at 750° C. for 2 hours, and Li₂CO₃ and CaCO₃, which are sintering aids, were weighed out and then mixed and pulverized. The resulting mixture was dried and 5 wt % of polyvinyl alcohol aqueous solution (PVA aqueous solution) was added thereto. The mixture was molded using a 17φ molder under a molding pressure of 15 MPa. Burn out was then performed at 600° C. for 3 hours to burn out the PVA binder. The prepared sample was sintered with a rising dropping temperature gradient of 3° C./min at a sintering temperature of 920° C. for 1.5 hours. The sintered sample was polished in 1 mm and both sides thereof were coated with an Ag electrode by using a screen printing method and then heat-treated at 600° C. for 10 minutes to determine electric properties. The sample was polarized by applying 3 kV/mm of DC electric field in silicon oil at 120° C. for 30 minutes. Resonance and antiresonance frequency and resonant resistance were determined by using an impedance analyzer (Agilent 4294A) according to the IEEE standard to obtain electromechanical coupling coefficient (k_{P}) and mechanical quality coefficient (Qₘ) 24 hours later after polarization. Microstructure and crystal structure of the sample were determined by using SEM (Scanning Electron Microscope) and XRD (X-ray Diffraction), respectively. Electrostatic capacity was determined at 1 kHz of frequency using an LCR meter (ANDO AG-4304) to obtain a dielectric constant in order to determine dielectric property of the sample. Piezoelectric constant (d₃₃) was determined by using a piezo-d₃₃ meter (APC, YE 2730A)

1) Dielectric and Piezoelectric Properties

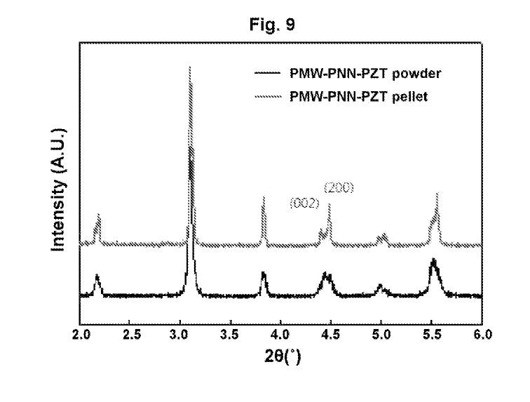

FIG. 9 illustrates X-ray diffraction patterns of final powders of a PMW-PNN-PZT+BiFeO₃ composition and the sintered pellet thereof. The samples were prepared by sintering at 920° C. using a conventional mixed-oxide method. It is noted from XRD patterns that the samples have a morphotrophic phase boundary having a rhombohedral phase and tetragonal phase and the sintered pellet shows strong a (200) peak of intensity and has a tetragonal phase. However, a secondary phase (pyrochlore) was not observed in both samples.

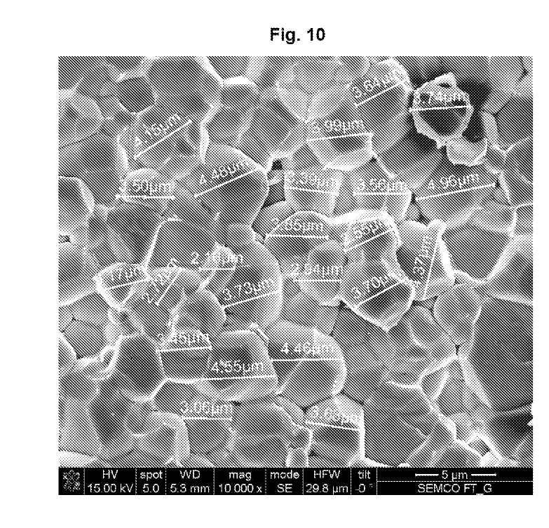

FIG. 10 illustrates a SEM image of PMW-PNN-PZT+BiFeO₃ ceramics. The sample was prepared by using a mixed-oxide method at a sintering temperature of 920° C. The average particle size of the sample was 3.69 μm.

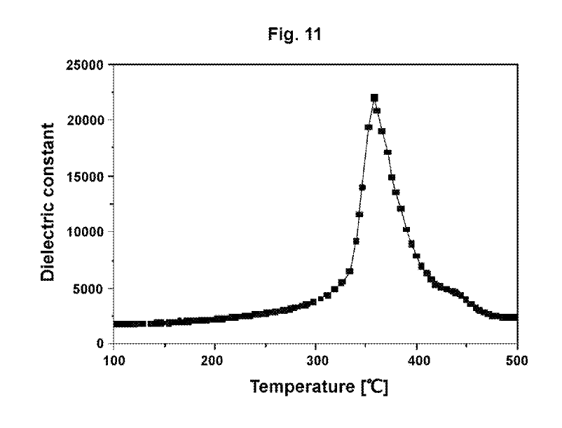

FIG. 11 illustrates the temperature dependence of dielectric constant of PMW-PNN-PZT+BiFeO₃ ceramics which are sintered at 920° C. by using a conventional mixed-oxide method. It is noted that Curie temperature is around 358° C.

TABLE 2

| | Electromechanical | Electromechanical | | Piezoelectric | Piezoelectric | Coercive |
|---|---|---|---|---|---|---|
| | coupling coefficient | coupling coefficient | Dielectric | constant (d₃₃) | constant (d₃₁) | field(Ec) |
| Process | (kp) | (k₃₁) | constant | [p C/N] | [p C/N] | [kV/cm] |
| Comp. | 0.62 | 0.37 | 2256 | 582 | 220 | 11.1 |
| Exam. | | | | | | |
| Exam. | 0.64 | 0.44 | 2549 | 621 | 248 | 10.05 |

Table 2 exhibits physical properties according to methods for preparing PMW-PNN-PZT+BiFeO₃ ceramics. B-site material was first calcinated at 1100° C., second calcinated at 750° C. and sintered at 920° C. using a columbite precursor method. Piezoelectric and dielectric properties of the sintered sample were increased, compared to those of the sample prepared by using a general sintering method. Particularly, electromechanical coupling coefficient (kp), dielectric constant (∈r), and piezoelectric constant (d₃₃) were significantly increased by calcinating the B-site material. NiNb₂O₆ from NiO and Nb₂O₅ was prepared more when the B-site material was first calcinated, compared to the general sintering method so that overall properties were improved.

Preparation of Samples III

A basic composition of the present Examples is as follows and samples are prepared by employing a mixed-oxide method. The method for preparing the samples is the same as in “Preparation of samples II”, except for the composition.

(1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃+0.2 wt % LiCO₃+0.25 wt % CaCO₃ (Composition 3)

TABLE 3

| | | | | Piezoelectric | |
|---|---|---|---|---|---|
| | | Dielectric | Electromechanical | constant(d₃₁) | Coercive field(Ec) |
| x | y | constant (εᵣ) | coupling coefficient (k₃₁) | (pC/N) | (kV/cm) |
| 0 | 0.47 | 2415 | 0.29 | 202 | 12.1 |
| | 0.48 | 2498 | 0.34 | 218 | 10.9 |
| | 0.49 | 2467 | 0.37 | 220 | 9.5 |
| | 0.50 | 2247 | 0.37 | 203 | 8.4 |
| | 0.51 | 1876 | 0.34 | 172 | 7.1 |
| | 0.52 | 1354 | 0.28 | 132 | 5.8 |
| | 0.53 | 754 | 0.20 | 87 | 4.9 |
| 0.0075 | 0.47 | 2238 | 0.26 | 177 | 15.9 |
| | 0.48 | 2463 | 0.33 | 215 | 14.4 |
| | 0.49 | 2502 | 0.36 | 231 | 12.8 |
| | 0.50 | 2405 | 0.38 | 220 | 11.6 |
| | 0.51 | 2097 | 0.36 | 201 | 10.3 |
| | 0.52 | 1624 | 0.30 | 162 | 8.7 |
| | 0.53 | 1054 | 0.23 | 110 | 7.4 |
| 0.015 | 0.47 | 2198 | 0.25 | 167 | 16.1 |
| | 0.48 | 2403 | 0.32 | 208 | 14.5 |
| | 0.49 | 2507 | 0.36 | 226 | 13.1 |
| | 0.50 | 2478 | 0.38 | 223 | 11.7 |
| | 0.51 | 2197 | 0.36 | 203 | 10.4 |
| | 0.52 | 1764 | 0.31 | 164 | 9 |
| | 0.53 | 1167 | 0.24 | 116 | 7.6 |
| 0.015 | 0.47 | 2176 | 0.25 | 164 | 13.7 |
| (Bi₂O₃, | 0.48 | 2315 | 0.32 | 203 | 12.1 |
| Fe₂O₃ | 0.49 | 2425 | 0.35 | 224 | 10.4 |
| additionally | 0.5 | 2365 | 0.37 | 219 | 9.3 |
| added) | 0.51 | 1978 | 0.34 | 192 | 8 |
| | 0.52 | 1517 | 0.28 | 152 | 6.3 |
| | 0.53 | 968 | 0.21 | 97 | 5.1 |

1) Dielectric and Piezoelectric Properties

Piezoelectric compositions having d₃₁ of 190 or higher, k₃₁ of 0.30 or higher, Ec 9.0 kV/cm usually show enough performance for actuator applications and the composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃+0.2 wt % LiCO₃+0.25 wt % CaCO₃ shows excellent properties in broad ranges of x and y.

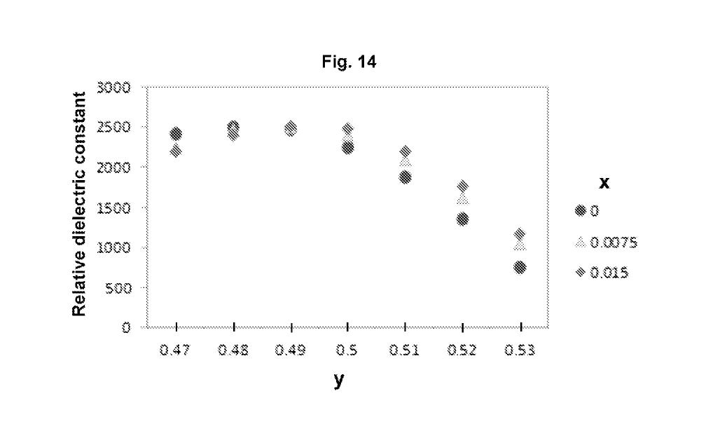

A haptic actuator which is small and requires a high vibration requires materials having an excellent piezoelectric property and a high coercive field, such as properties of d₃₁ 220 or higher, k₃₁ 0.35 or higher, Ec 11.0 kV/cm or higher due to a high driving electric field. As shown in Table 3, a composition with all satisfied properties cannot be obtained among the compositions which do not include BiFeO₃. However, when Pb was substituted by 0.75, 1.5m/o BiFeO₃, all compositions exhibit satisfied properties due to an increase in Ec as shown in FIG. 14 (Zr/Ti: 49/51-50/50).

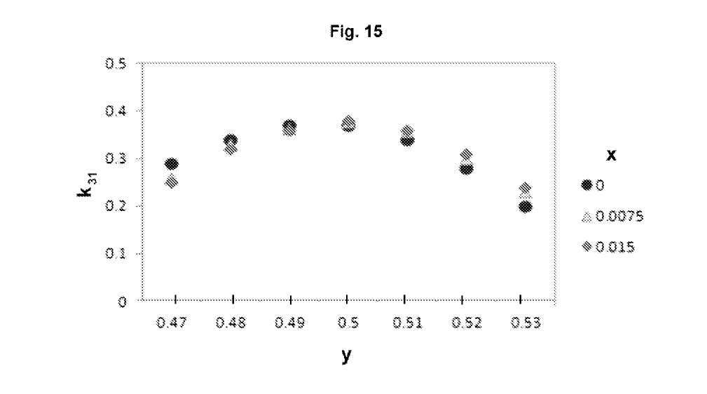

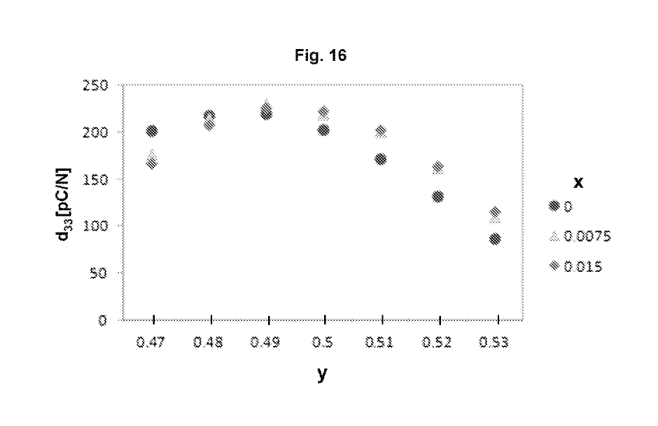

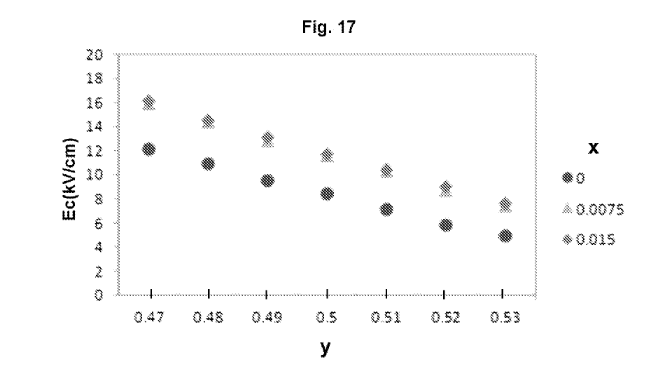

FIG. 14 is a graph illustrating dielectric constants depending on Zr/Ti ratios, FIG. 15 is a graph illustrating electromechanical coupling coefficients depending on Zr/Ti ratios, FIG. 16 is a graph illustrating piezoelectric constants depending on Zr/Ti ratios, and FIG. 17 is a graph illustrating coercive fields depending on Zr/Ti ratios, which support the result shown in Table 3.

Referring to Table 3, it is noted that when x=0, only compositions with y=0.48, 0.49 show properties useful for actuator application, while when x=0.0075 and x=0.015, the compositions with y=0.48-0.51 show properties useful for actuator application. Particularly, it is noted that when x=0.0075 or x=0.015 and y=0.49 or 0.50, demanding properties for haptic actuator application are satisfied.

In ABO₃ type perovskite structure, a large-sized atom of 2⁺ ion is positioned in the A site and a smaller-sized atom of 4⁺ ion is positioned in the B site. When an atom of 3⁺ or less ion is substituted in the B site where the atom of 4⁺ ion exists, it functions as an acceptor and oxygen vacancy is formed to keep the entire crystal structure in neutral. In general, coercive field increases while dielectric and piezoelectric properties decrease when an acceptor is substituted. Furthermore, reliability deteriorates due to a transfer of oxygen vacancies under conditions of high temperature and high electric field. On the other hand, when the atom of 2⁺ ion in the A site is substituted by atom of 3⁺ ion, it functions as a donor and a Pb vacancy is formed to keep the entire crystal structure in neutral which further increases dielectric and piezoelectric properties. When such defects are caused, it facilitates mass transfer which promotes sinterability and piezoelectric properties. When Fe₂O₃ alone, as an acceptor, is added to PMW-PNN-PZT, the coercive field is increased but the piezoelectric property rapidly decreases due to deformation of crystal lattice structure. However, when Bi₂O₃ is added in the same mole ratio as Fe₂O₃, deformation of the crystal lattice structure can be minimized and the coercive field can be increased without deteriorating the piezoelectric property.

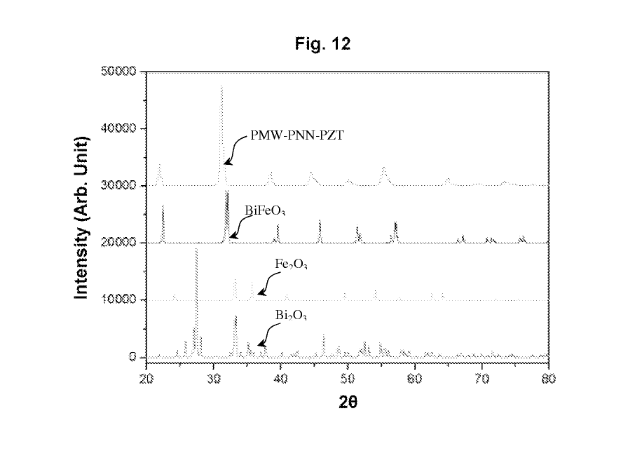

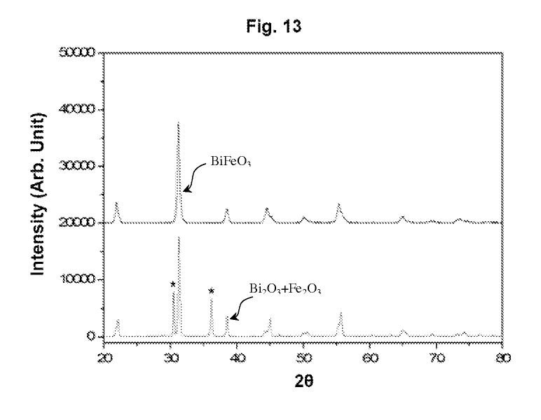

When Bi₂O₃ and Fe₂O₃ are added instead of BiFeO₃, an improvement of Ec is less and the secondary phase is formed since it is difficult to control defects in the A site and the B site equally. FIG. 12 and FIG. 13 illustrate X-ray diffraction patterns depending on various sintering aid types to be added to a PMW-PNN-PZT ceramic composition. As shown in XRD patterns of Bi₂O₃ and Fe₂O₃, it is noted that the crystal structures thereof are different from the piezoelectric PMW-PNN-PZT, while BiFeO₃ has a perovskite structure identical to the piezoelectric PMW-PNN-PZT. Accordingly, it minimizes structure deformation which does not deteriorate the piezoelectric property.

The spirit of the present disclosure has been described by way of example hereinabove, and the present disclosure may be variously modified, altered, and substituted by those skilled in the art to which the present disclosure pertains without departing from essential features of the present disclosure. Accordingly, the exemplary embodiments disclosed in the present disclosure and the accompanying drawings do not limit but describe the spirit of the present disclosure, and the scope of the present disclosure is not limited by the exemplary embodiments and accompanying drawings. The scope of the present disclosure should be interpreted by the following claims and it should be interpreted that all spirits equivalent to the following claims fall within the scope of the present disclosure.

What is claimed is:

1. A piezoelectric ceramic composition comprising a basic composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃, wherein x=0 or 0.015 and y=0.47-0.53, and at least one sintering aid selected from the group consisting of LiCO₃, CaCO₃, PbO, CuO and Fe₂O₃.

2. The piezoelectric ceramic composition of claim 1, wherein the sintering aid is 0.2 wt % LiCO₃ and 0.25 wt % CaCO₃ based on a total weight of the piezoelectric ceramic composition.

3. The piezoelectric ceramic composition of claim 1, wherein the sintering aid is 0.3 wt % PbO, 0.3 wt % CuO, and 0.1-0.4 wt % Fe₂O₃ based on a total weight of the piezoelectric ceramic composition.

4. A piezoelectric element comprising the piezoelectric ceramic composition of claim 1.

5. The piezoelectric element of claim 4, further comprising an internal electrode layer formed on at least one of a top and a bottom of the piezoelectric layer.

6. The piezoelectric element of claim 5, wherein the internal electrode layer comprises an Ag—Pd alloy.

7. The piezoelectric element of claim 6, wherein the internal electrode layer comprises a palladium content of from more than 0 wt % to 10 wt % in the Ag—Pd alloy.

8. The piezoelectric element of claim 4, wherein the piezoelectric element is a piezoelectric actuator.

9. A method for preparing a piezoelectric ceramic composition comprising:
mixing or combining PbO, MgO, WO, NiO, Nb₂O₅, ZrO₂, and TiO₂ to prepare a basic composition to be (1-x)Pb(Mg_{1/2}W_{1/2})_{0.03}(N_{1/3}Nb_{2/3})_{0.09}(Zr_{y}Ti_{1-y})_{0.88}O₃+xBiFeO₃, wherein x=0, 0.0075, or 0.015, and y=0.47-0.53;
performing a first calcination after mixing the MgO, WO, NiO, Nb₂O₅, ZrO₂, and TiO₂ to form a first calcinated sample;
performing a second calcination after mixing and pulverizing the first calcinated sample and PbO to form a second calcinated sample;
mixing PbO, CuO and Fe₂O₃ or LiCO₃ and wt % CaCO₃ to the second calcinated sample and pulverizing the mixture; and
sintering the mixture.

10. The method for preparing a piezoelectric ceramic composition of claim 9, wherein the composition comprises: 0.3 wt % PbO, 0.3 wt % CuO, and 0.1-0.4 wt % Fe₂O₃ based on a total weight of the composition.

11. The method for preparing a piezoelectric ceramic composition of claim 9, wherein the composition comprises: 0.2 wt % LiCO₃ and 0.25 wt % CaCO₃ based on a total weight of the composition.

12. The method for preparing a piezoelectric ceramic of claim 9, wherein the sintering is performed at a temperature of 900° C.-940° C. for 2 hours.

13. The method for preparing a piezoelectric ceramic composition of claim 12, wherein the sintering is performed at the temperature of 900° C.-940° C. for 2 hours, with a rising or dropping temperature gradient of 3° C./min from or to a reference temperature.

14. A piezoelectric ceramic composition comprising a composition of (1-x)Pb(Mg_{1/2}W_{1/2})_{0.03}(Ni_{1/3}Nb_{2/3})_{0.09}(Zr_{y}Ti_{1-y})_{0.88}O₃+xBiFeO₃, wherein x=0-0.015 and y=0.47-0.53, and at least one sintering aid selected from the group consisting of LiCO₃, CaCO₃, PbO, CuO and Fe₂O₃.

15. The piezoelectric ceramic composition of claim 14, wherein, when x=0, y is from 0.48 to 0.49.

16. The piezoelectric ceramic composition of claim 14, wherein, when x=0.0075-0.015, y is from 0.48 to 0.51.

17. The piezoelectric ceramic composition of claim 14, wherein the composition comprises 0.2 wt % LiCO₃ and 0.25 wt % CaCO₃ based on a total weight of the composition.

18. The piezoelectric ceramic composition of claim 14, wherein the composition comprises 0.1-0.4 wt % Fe₂O₃ based on a total weight of the composition.

19. The piezoelectric ceramic composition of claim 18, wherein the composition further comprises 0.3 wt % PbO and 0.3 wt % CuO.
